(19) United States
(12) Patent Application Publication
(10) Pub. No.: US 2014/0091689 A1
(43) Pub. Date: Apr. 3, 2014

(54) Cover Having Wallet Feature for Electronic Devices

(71) Applicant: E. MISHAN & SONS, INC., New York, NY (US)

(72) Inventors: Dylan MISHAN, New York, NY (US); Jenna Marie EDGEMON, Brooklyn, NY (US); Stuart Harvey LEE, Forest Hills, NY (US)

(73) Assignee: E. MISHAN & SONS, INC., New York, NY (US)

(21) Appl. No.: 13/630,870

(22) Filed: Sep. 28, 2012

(51) Int. Cl. H05K 5/02

(52) U.S. Cl. CPC H05K 5/02
USPC 312/237; 312/223.1

(57) ABSTRACT

A safety cover for an electronic device has a tray with a floor, the floor having inner and outer surfaces, ribs on the inner surface, and side walls. The floor includes at least one recess and at least two spaced apart slots extending through the floor. A flexible elastic band extends over part of the outer surface of the tray floor which is between two slots. The band has two flaps, each extending through a slot into a recess and being adhered inside a recess to secure the elastic band. A cover plate covers the flaps inside the tray and provides a flat surface to engage the device. The elastic resiliently receives items to be held by the cover arrangement.

### FIELD AND BACKGROUND OF THE INVENTION

The present invention relates generally to the field of electronic device protective cases, and, in particular, to a new and useful safely cover for electronic devices that includes a wallet or pocket feature having flexible dimensions so that the case will always have the thinnest possible cross-section.

In recent years there has been a proliferation of portable electronic gadgets and devices such as portable MP3 players, smart phones, navigation devices, electronic readers, and touch-screen computers. Since the 1990's these devices have become common everyday items. Although these devices are typically fragile and expensive, often including breakable components such as touch-sensitive display screens, many users carry them wherever they go.

Cases and covers are known for covering at least the backs and sides of electronic devices such as portable phones, smart phones, mobile phones, portable computing devices, portable digital data storage and playback devices, handheld personal electronic devices, digital media player devices, audio and video players, personal digital assistants, handheld wireless devices, handheld digital audio and/or video capture devices, digital cameras, digital camcorders, GPS devices, electronic games, electronic book readers, and other devices which are mostly rectangular, usually relatively thin, and often susceptible to damage if they are dropped or mechanically impacted.

A variety of cases have been devised for protecting electronic devices which include additional features. Examples include Published Patent Application US2011/0077061 for a cell phone case having a hinged back cover where interchangeable trays which can be installed for holding personal items such as makeup and cards (application Ser. No. 12/964,583), and Published Patent Application US2011/0089077 which discloses a compartmentalized case with several compartments for an electronic device, for personal care items, cards, or currency (application Ser. No. 12/589,210). See also Published Patent Applications US2006/0172765, US2006/0052064, US2006/0010588, US2010/0006468, and U.S. Pat. Nos. 5,265,720, 6,626,362, 7,050,841, and 5,360,108.

Portable electronic devices must, with few exceptions, be light and compact. Smart phones and portable MP3 players are typically small enough to carry in a pocket or a small purse. Touch-screen computers and electronic readers may be the size of a magazine or a book, and often well under half an inch thick. These devices could be made more cheaply and easily if they were larger, but consumers are willing to pay for devices which pack the most features into the smallest space. As a result, electronic devices are often marketed by emphasizing how sleek and slim the devices are.

It follows that most users prefer cases and covers which protect their device with minimal addition to the size, thickness, and weight of the device. For example, a smart phone owner wants to protect his or her expensive device without making it so large that it will not fit comfortably in their pocket. Touch screen computer owners will avoid protective cases that double the thickness of their sleek, thin computer.

At the same time, it can be advantageous to add additional features to a protective case, since users will be carrying the encased devices around with them. For example, a pocket-sized phone case could also provide wallet functionality. A tablet computer or electronic reader case could include a means to hold papers, pens, notebooks, CDs, or computer accessaries. Prior art cases having added carrying means include additional unnecessary material, however, adding undesirable bulk and thickness to the case. Thus, there is a need for an inexpensive electronic device cases having added means for carrying additional items which do not add significant thickness, size, or weight to the case.

### SUMMARY OF THE INVENTION

It is an object of the present invention to provide a safety cover for covering at least the back and sides of an electronic devices such as, but not limited to, portable phones, smart phones, mobile phones, portable computing devices, tablet computers, portable digital data storage and playback devices, handheld personal electronic devices, digital media player devices, audio and video players, personal digital assistants, handheld wireless devices, handheld digital audio and/or video capture devices, digital cameras, digital camcorders, GPSs, electronic games, eBook readers and other devices that are mostly rectangular or, more generically, polygonal, relatively thin, and susceptible to damage when dropped or mechanically impacted.

It is a further object of this invention to provide a protective cover having a means for securely holding a variety of items without significantly increasing the thickness of the protective cover.

Accordingly, a protective case is provided which has at least one flexible elastic band stretched across the back of the case adapted for securely holding items against the case. This configuration is advantageous because the elastic band pulls tight against the back of the case when no item is inserted, adding almost no thickness to the case. The elastic can then expand—but only when necessary—just enough to accommodate items to be carried by the case. This provides an advantage over prior art wallet-cases which do not expand and contract, and thus either only hold very thin items, or else add far more undesirable thickness than the present invention.

Another key feature of the instant invention is utilizing the back of the case itself—which is also the floor of the tray—to form one side of the holding means, thus avoiding the need to add additional material which increase the case's cross section. The elastic band is fixed in a depression or recess in the opposite side of the same floor, which further conserves space and minimizes thickness.

Another advantage of the invention is that it is simple to manufacture, and simple to adapt for use with different electronic devices or even with some prior art protective cases. For example, the same elastic band concept and attachment method can be used to add wallet functionality to any phone, or to add folder functionality to any tablet computer or electronic reader.

According to one aspect of the invention, a case for an electronic device having an added wallet or folder feature comprises a tray having a floor adapted to cover a rear surface of an electronic device in the tray, the floor having an outer surface, an inner surface, a plurality of ribs on the inner surface, and a perimeter. The tray also has a plurality of side walls connected to the perimeter of the floor and extending around some or all of the perimeter and adapted to cover respective sides of an electronic device in the tray. The floor includes at least one recess, the one or more recesses being defined by the ribs and the side walls. At least two spaced apart slots extend from recess through the floor.

A flexible elastic band extends over at least part of the outer surface of the floor between two slots, the band being for resiliently receiving items to be stored between the band and the outer surface of the floor. The band has at least two opposite flaps, each flap extending through at least one of the slots and into a recess, each flap being adhered to the inner surface of the floor in a recess to secure the band to the floor.

A cover plate is attached to the floor, the ribs, and/or the flaps. The cover plate covers most of all of the floor, the ribs, and the flaps, and also forms the back of a cavity for holding the electronic device.

The case has an empty state wherein the case does not hold any extra items and the elastic band is pulled flat against the outer surface of the floor. The case also has a “holding” state wherein the elastic band is stretched away from the outer surface of the case just far enough to accommodate items being stored in the case, and wherein the elastic band exerts pressure on the stored items towards the outer surface of the floor to hold the items against the case.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which a preferred embodiment of the invention is illustrated.

### BRIEF DESCRIPTION OF THE DRAWINGS

In the drawings:

FIG. 1 is a top perspective view of the back a case for an electronic device having a flexible elastic band;

FIG. 2 is bottom perspective view of the front of the case in FIG. 1 showing the cavity where the electronic device to be protected would sit;

FIG. 3 is an exploded view of an alternative embodiment of the invention showing a cover plate, a tray, and an elastic band;

FIG. 4 is an exploded view of a further alternative embodiment of the case showing a cover plate, a tray, and an elastic band;

FIG. 5 is a plan view of the front of a phone device held by a case of the present invention;

FIG. 6 is a plan view of the back of the phone device and case of FIG. 5 showing a small part of the phone device through an opening in the case, and a card being held by the elastic band.

FIG. 7 is a plan view of the inside of a tray having two flaps of an elastic band fixed in two recesses.

### DESCRIPTION OF THE PREFERRED EMBODIMENTS

The thin protective cases having elastic bands for resiliently receiving items of present invention can easily be adapted for use with electronic devices of a variety of shapes and sizes, particularly devices that are relatively thin and flat. Example cases suited for smart phones are herein provided to illustrate the concept of invention, although the invention is not limited to phone cases.

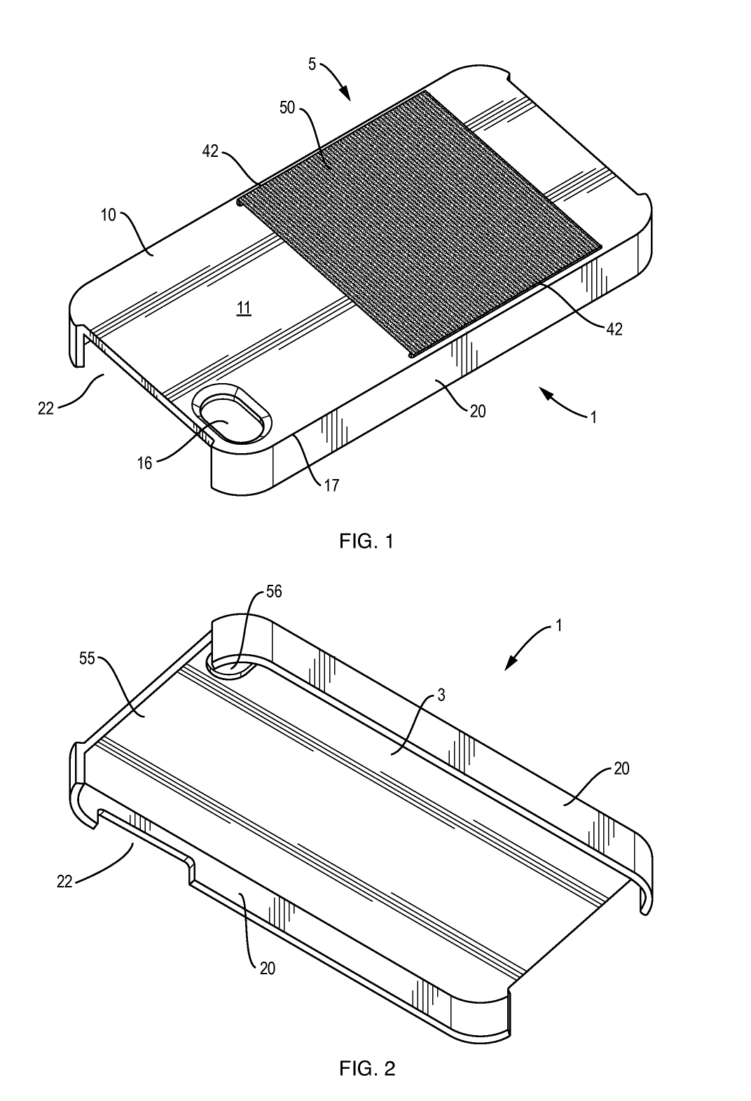

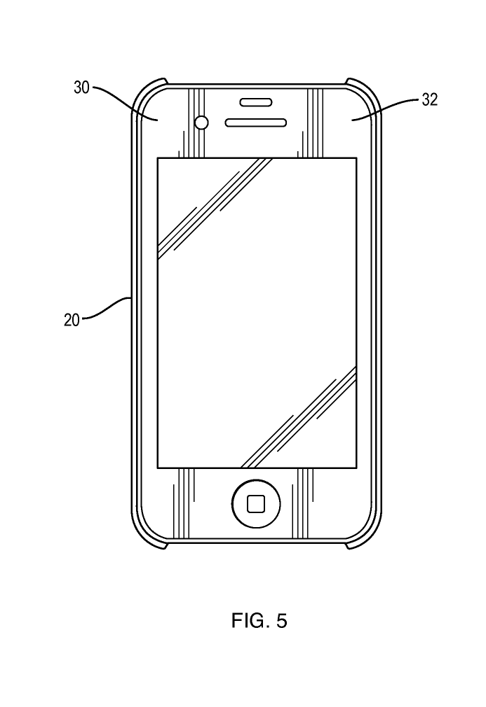

Referring now to the drawings, in which like reference numerals are used to refer to the same or similar elements, FIGS. 1-6 illustrate a case 1 for protecting a smart phone having a touch screen placed in a cavity 3 of the case.

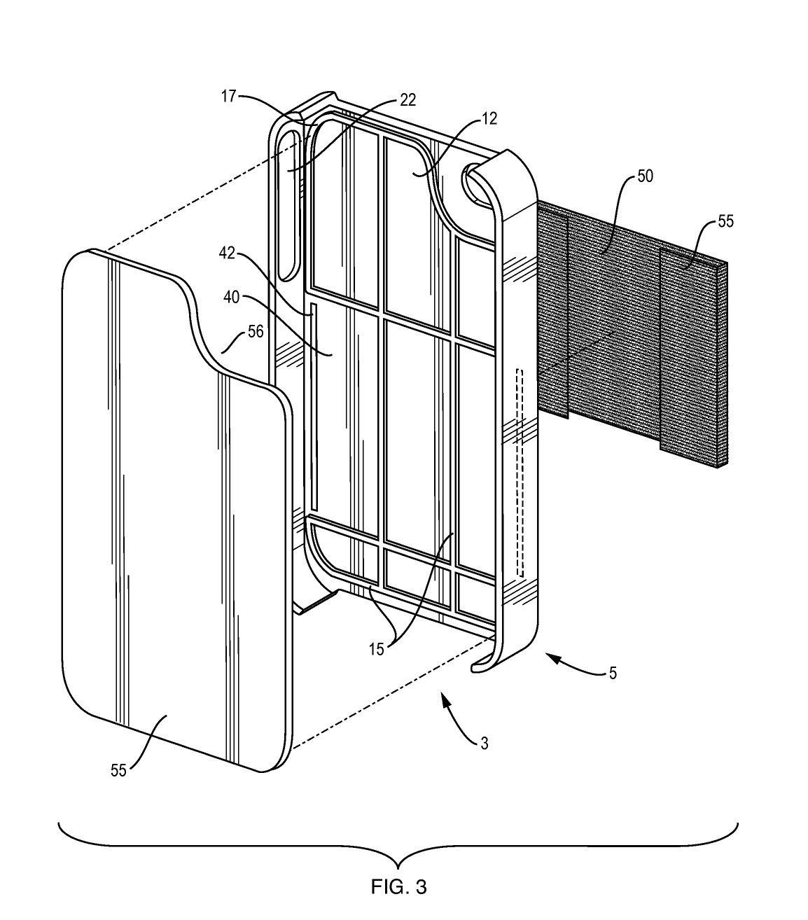

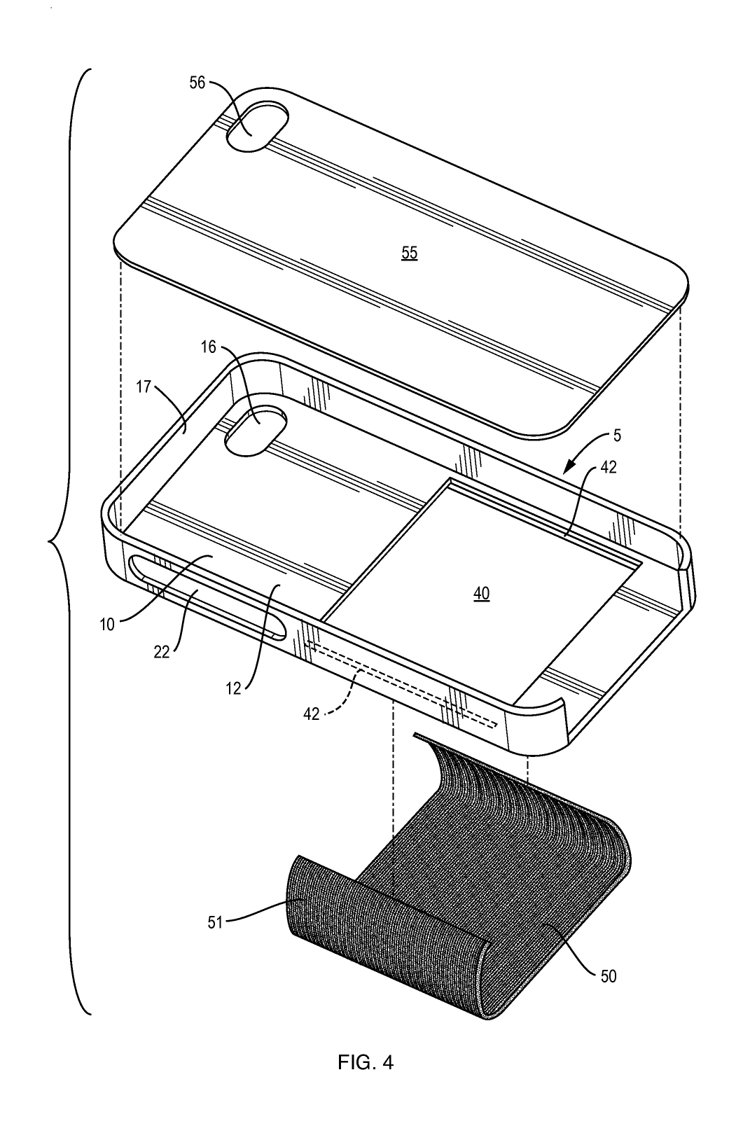

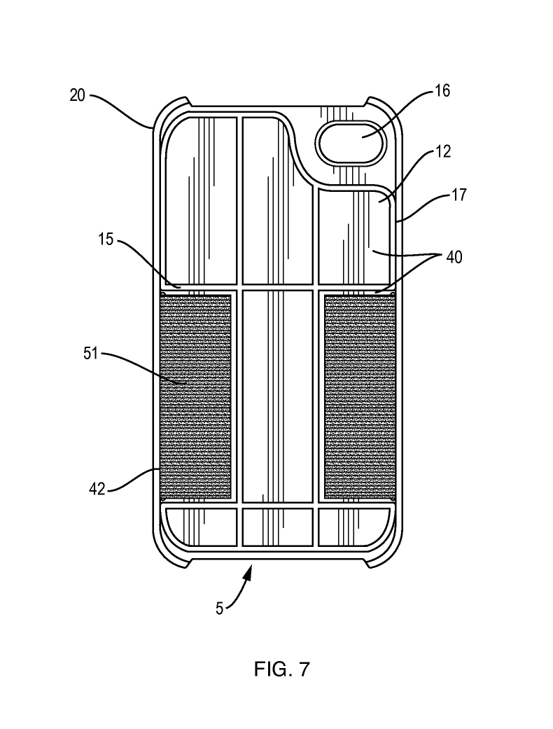

The central component of the protective case 1 is a tray 5 having a back or floor 10 which has the approximate dimensions of a back surface 31 or other surface of an electronic device 30 to be held in the case. For example, the floor 10 of the tray 5 shown in FIGS. 1-2 and 7 has nearly the same dimensions as an Apple™ iPhone™, a type of “smart” internet-enabled phone having a touch screen. The floor has an outer surface 11, an inner surface 12, and a perimeter 17. FIG. 1 points out the back of a tray in a fully assembled case, while exploded FIGS. 3 and 4 show examples of trays 5 separate from the other components. FIG. 7 shows the inside of a tray 5 where the attached flaps 51 of an elastic band 50 are visible because the cover plate 55 is not shown.

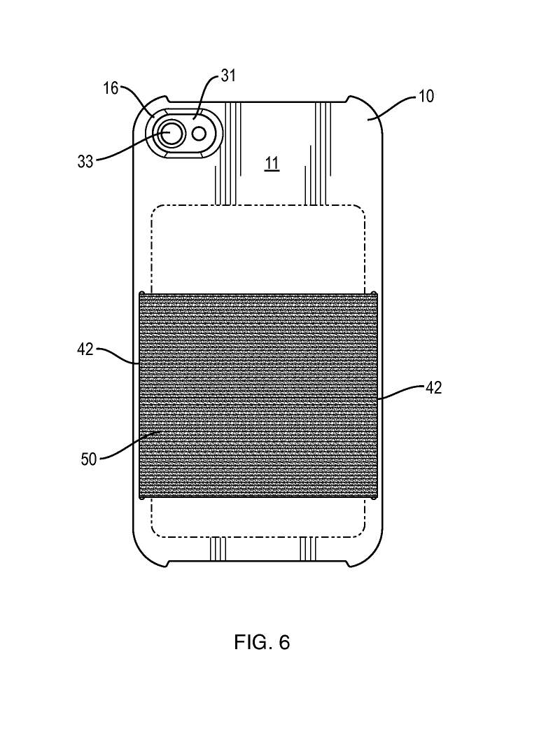

The floor may also include holes or openings 16 tailored to specific electronic devices so that various features of the devices can be seen or accessed by the user. FIG. 6, for example, shows a case having a floor opening 16 in the floor 10 for a lens 33 of a phone which includes a camera function. The thickness of the floor is preferably minimized, to make the case as thin as possible, but it can also be thicker for added strength and device protection.

The tray 5 includes a plurality of side walls 20 connected to the perimeter 17 of the floor. The side walls are adapted to cover the sides of the electronic device 30 when the device is in the case, and may be made of the same material or a different material as the floor 10 of the tray 5. Preferably the side walls are tailored to accommodate the shape and thickness of each specific electronic device. The side 20 walls are preferably designed to help hold the electronic device in the case, such as by squeezing pressure and/or by providing a rim that holds the device 30 in the case by engaging part of the front 32 of the device. The side walls 20 may encircle the entire perimeter 17 of the floor and of the device. Alternatively, as shown in FIGS. 1-4, the side walls may be intermittent or may include breaks, cutouts, or openings 22. Openings 22 in the side walls are also preferably tailored to each device to be protected, such as to allow access to switches, buttons, speakers, microphones, plug holes, or other features located on the sides of the particular device. Openings 22 or intermittent walls can also be adapted to reduce the amount of material used for the case to reduce weight, to provide flexibility to the case, and/or as part of the means for inserting and releasing the device from the case.

The floor preferably includes at least one recess 40, and may include many recesses. One or more recesses 40 connect with a total of two or more spaced apart slots 42 extending through the floor 10 to the back of the case. FIG. 3 shows a tray 5 where the inner surface 12 of the floor includes approximately nine recesses defined by the side walls 20 and by a network of raised ribs 15. In FIG. 3 one slot 42 is visible near a side wall, and a matching slot is obscured by the opposite side wall. FIG. 4 shows two slots at the edges of a sunken recess 40. FIGS. 1 and 6 show two parallel slots 42 from the outer surface 11 at the back of the case, as well as flexible elastic bands 50 extending through the slots.

The case includes at least one flexible elastic band 50 extending over at least part of the outer surface 11 of the floor and stretching between the slots 42 for resiliently receiving items to be stored between the band and the floor (See FIGS. 1 and 6). The band 50 comprises, or alternatively is attached to, at least two opposite flaps 51, each flap extending through one of the slots and into a recess 40. Preferably the flaps 51 are merely a continuation of the elastic band 50, although different materials and additional components may also be used to form the flaps, such as for improved attachment to the tray. Each flap 51 is fixed to the inner surface 12 of the floor, preferably within a recess. The flaps are preferably fixed using strong adhesive. Alternatively, flaps at opposite ends of the same band can be fixed to each other to form a loop going around both sides of the floor and through the slots 42.

Preferably the elastic band 50 pulls itself flat against the outer surface 11 of the floor 10 of the case 1 when it is empty, i.e. not storing any items, in the “empty state”. FIG. 1 shows a case 1 in the empty state, and further how an empty band 50 adds almost no thickness to the case. Items can be inserted between the elastic band 50 and the outer surface 11 of the tray 5 for storage. Preferably the elastic band stretches out just far enough to accommodate items being stored in the “holding state”, and maintains a constant pressure on the item(s) in the direction of the tray floor 10 to securely hold them against the outer surface 11 of the tray floor 10. FIG. 6 illustratively shows a credit card being held against the case 1 by an elastic band 50, although preferred embodiments can hold more and/or larger items.

In the preferred embodiment shown in FIG. 6, the storage space between the band 50 and the tray 5 is open at two ends. Alternative embodiments where a third side of the band 50 is attached to the tray 5 to form a pocket with only one opening may also be desirable. This third side attachment may be achieved using additional slots 42 and flaps 51, using adhesive, or otherwise.

With reference to FIG. 3, in a preferred embodiment the floor 10 includes ribs 15 on the inner surface 12. The ribs 15 can be adapted to create a small clearance between the inner surface 12 of the floor 10 and the cover plate 55. This clearance between the floor 10 and the cover plate 55 can improve the protection provided to electronic devices by the case 1 by creating space between the device 30 and possible impact points, thereby dampening many impacts. The ribs 15 can also be used to define one or more recesses 40 in the floor. Ribs 15 can be arranged to provide additional strength and rigidify to the case if desired. The ribs 15 may be thin, raised rectangular ridges, as shown in FIG. 3, but many other shapes and arrangements are possible and within the scope of the invention. In a preferred embodiment the ribs 15 are manufactured as a part of the floor 10 of the tray 5 itself. Alternatively, ribs 15 may be added separately and/or may comprise different materials than the other parts of the tray 5. Preferably the ribs 15 are relatively short to avoid adding unnecessary thickness to the case 1.

A cover plate 55 is positioned on or above the inner surface 12 of the floor 10 and within the side walls 20, as shown in the exploded illustrations in FIGS. 3-4. The cover plate 55, together with the side walls 20, generally define the cavity 3 where the device 30 is positioned in the fully-assembled case 1. See also FIG. 2 where the cover plate 55 forms the largest wall of the cavity 3. The cover plate 55 may be attached to the inner surface 12 of the floor, to the ribs 15, and/or to the flaps 51, preferably using strong adhesive. In one preferred embodiment shown in FIG. 3, the cover plate 55 rests on the ribs 15, and preferably on the flaps 51 of the elastic band 50 as well.

Preferably the recesses 40 hold the flaps 51 of the elastic band 50 at or below the plane where the cover plate 55 is attached to the floor 10 and/or to the ribs 15. Preferably the cover plate 55 is adapted to reinforce the attachment of the flaps 51 of the elastic band 50 inside the tray 5 from above. This may be accomplished by attaching the flaps 51 to the plate 55 itself, such as by adhesive, and/or by positioning the plate 55 to squeeze the flaps between the plate 55 and the inner surface 12 of the floor 10. Preferably both approaches are used, in further combination with gluing the flaps 51 to the recesses 40 in the floor 10 of the tray 5.

The cover plate 55 is preferably sized to cover most or all of the floor 10, the ribs 15, and the flaps 51. The cover plate 55 is preferably planar, though other shapes to accommodate the shape of electronic devices, for added strength, or for better engaging the tray 5 or the flaps 51 are possible. FIG. 2 shows an embodiment where the plate 55 covers all of those components completely. FIG. 3 shows an alternative embodiment where the cover plate 55 has a notch 56 in one corner which leaves part of the floor exposed. Cover plates can include various gaps, notches, and plate openings 56 to accommodate different electronic devices. For example, the cover plate in FIG. 3 includes a corner notch 56 to accommodate a lens at the back of an electronic device 30 having a camera function, which can use used for an arrangement similar to FIG. 6. FIG. 4 shows a cover plate 55 having a hole for the same purpose as the notch 56 of FIG. 3. It will usually be desirable to align any openings 16 in the cover plate with similarly placed openings 16 in the floor of the tray.

In a preferred embodiment the cover plate 55 consists of the same materials and has the same color as the tray 5. The cover plate 55 most preferably appears to be unitary part of the tray 5 of the case 1 in the final product. Paint or other materials may be used to smooth over the interface between the cover plate 55 and the tray 5. In one embodiment the cover plate and the tray are both covered in colored soft touch spray-on paint.

The tray 5 and cover plate 55 of the present invention can be made from a variety of materials. In a preferred embodiment both comprise rigid plastic. Softer plastics, rubber-like materials, and soft materials coating rigid frames are also possible. Many suitable materials are known in the art which can also be used with this invention. Examples can be found, for example, in the references listed and discussed in the background section above. Preferably the cover plate 55 is relatively thin to minimize the overall thickness of the case 1.

In a most preferred embodiment, the electronic device case 1, including the floor 10 of the tray, the elastic band 50, any ribs 15, and the cover plate 55, are designed to have the minimum possible collective thickness. In one preferred embodiment, for use with a touch-screen phone, the case has a total thickness of 13.84 millimeters inclusive of the elastic band, which is only about 1 millimeter thick.

The case may include a cover (not shown) for part or all of the front of the electronic device which is not covered by the side walls or floor of the tray. Such cover may be transparent and/or may be openable similarly to the cover of a book or notebook. Various screen covers known in the art can be used with the present invention.

The recesses 40 in the floor 10 of the present invention can take a variety of forms to hold and receive the flaps 51 via slots 42. The purpose of the recesses is to provide space for the flaps 51 between the inner surface 12 of the floor 10 and the cover plate 55, which various different structures can achieve.

For example, the embodiment of FIG. 3 includes approximately nine recesses, two of which open into slots 42 (only one slot is visible in FIG. 3). The ribs 15 are arranged to separate the cover plate 55 from the floor 10, providing space for the flaps 51 in a recess 40. Many other arrangements of ribs 15 could achieve a similar result. There could be more recesses or fewer defined by different arrangements of the ribs and the side walls 20. Embodiments where two or more flaps 51 enter a single recess through two or more slots in the same recess 40 are also possible. The recesses 40 could also take the form of a sunken-in or thinner portion of the floor 10 which is below the plane of other parts of the inner floor surface 12, as shown in FIG. 4. Embodiments where the inner surface 12 of the floor 10 is flat, while one side of the cover plate 55 is used to define the recesses instead, such as with ribs 15, are also possible.

The elastic band 50 of the present invention is preferably a stretchable material that is thin, strong, and able to return to its original shape after being stretched many times. Nylon elastic is preferred, but other materials may be selected. In one preferred embodiment for a smaller electronic device 30, the resilient elastic band 50 stretches far enough to accommodate at least six standard credit cards, but is also tight enough to hold a single card securely against the floor, and to return to a fully flat position against the floor 10 when all items are removed. Persons of skill in the art will be able to determine proper lengths and widths of elastic to use for different sized cases and for holding different items. Similarly, bands having stronger or weaker elastic properties can be selected for different purposes.

Persons of skill in the art will appreciate that the elastic band 50 arrangement of the present invention can have many variations using different elastic bands and differently arranged slots. Embodiments comprising more than one band, either on top of each other, or arranged on different parts of the outer surface 11 of the case 1 to hold different sized items, are possible. In a preferred embodiment the band stretches most of the way across a portion of the outer surface 11 in the shorter dimension, as shown in FIGS. 1 and 6. The band or bands 50 can also stretch across the outer surface 11 in the longer dimension. More than one band 50 may be passed through a single slot 42, and more than two slots 42 may be provided. In a preferred embodiment, the band 50 and its respective slot 42 have nearly identical heights, as shown in FIG. 1. The band 50 may or may not extend all the way across the outside surface 11 in a given direction. Bands 50 can be designed for holding credit and ID cards, currency, papers, magazines, writing utensils, items for use with the electronic device, CDs, or most other items of reasonable size.

In a preferred embodiment the slots 42 are parallel to each other and have the same length and a narrow width, although embodiments where the slots 42 are different sizes or not parallel are possible. The slots 42 may be provided adjacent to opposing side walls 20 as shown in FIGS. 1, 3-4, and 7. Preferably the length of the slots 42 and the width of the band 50 to be used with the slot 42 are very similar so that excess slot 42 is not highly visible when the flaps are inserted into the slots 42. See FIG. 1.

The elastic bands 50 of the present invention are an improvement over the prior art because they can hold items of varying sizes and thicknesses while adding the minimum possible thickness to the protective case 1. As discussed in the background section, it is desirable that cases for protecting portable electronic equipment be as thin as possible. Prior art electronics cases for carrying items such as cards and currency include excess material that adds unnecessary thickness to the case. See, e.g., published patent applications US2011/0077061 and US2011/0089077. The instant elastic bands 50, preferably about one millimeter thick, add almost no extra weight or thickness to the case when they are not holding any items. See FIG. 1 showing an empty band 50 taught against the back of the case 1, not adding significantly to the thickness of the case 1. When items are being held by the band 50 against the outer surface 11, the flexible band expands no more than is necessary to accommodate each item. This is an improvement over prior art cases with carrying compartments having more fixed, defined shapes that cannot expand and contract as needed. This is particularly useful for consumers who would occasionally like to carry credit cards or cash in their phone case, but who prefer the smallest possible case that will fit comfortably in their pocket. Similarly, touchscreen or tablet computer owners and electronic reader owners can occasionally slip cards, papers, notebooks, CDs, or similar items into their computer case without permanently increasing the effective thickness of their computer with a thick case having a pocket of fixed thickness.

While several specific embodiments of the invention have been shown and described in detail to illustrate the application of the principles of the invention, it will be understood that the invention may be embodied otherwise without departing from such principles. In some embodiments of the invention, certain features of the invention may sometimes be used to advantage without a corresponding use of the other features. Accordingly, all such changes and embodiments properly fall within the scope of the following claims.

What is claimed is:

1. A case (1) for an electronic device (30) with added storage feature comprising:
a tray (5) having a floor (10) adapted to cover a rear surface (31) of an electronic device (30) in the tray, the floor having an outer surface (11), an inner surface (12), a plurality of ribs (15) on the inner surface (12), and a perimeter (17), the tray (5) also having a plurality of side walls (20) connected to the perimeter of the floor and extending around some or all of the perimeter (17) and adapted to cover respective sides of the electronic device (30) having a rear surface (31) in the tray, the floor comprising one or more recesses (40), the one or more recesses (40) being defined by the ribs (15) and, the floor (10) also comprises at least two spaced apart parallel slots (42) extending there through;
a flexible elastic band (50) extending over at least part of the outer surface (11) of the floor and between the slots (42) for resiliently receiving items to be stored between the band (50) and the outer surface (11) of the floor (10), the band (50) having at least two opposite flaps (51), each flap (51) extending through at least one of the slots (42) and into one of the recesses (40), each flap (51) being adhered to the inner surface of the floor (10) in the at least one recess (40) for securing the band (50) to the floor (10); and
a generally planar cover plate (55) adhered to at least one of the floor (10), the ribs (15), and the flaps (51), the cover plate (55) being sized to substantially cover the floor (10), the ribs (15), and the flaps (50), the cover plate (55) also being positioned for contacting the rear surface (31) of the electronic device (30);
the elastic band (50) is adapted to lie flat against the outer surface (11) of the floor (10); and
wherein the elastic band (50) is adapted to be stretched away from the outer surface (11) of the floor far enough to accommodate against the outer surface (11) of the floor (10), and wherein the elastic band (50) is adapted to exert pressure on the items in the direction of the outer surface (11) of the floor (10) to hold the items against the outer surface (11).

2. A case (1) for an electronic device (30) with added storage feature comprising:
a tray (5) having a floor (10) adapted to cover a rear surface (31) of an electronic device (30) in the tray (5), the floor (10) having an outer surface (11), an inner surface (12), and a perimeter (17), the tray (5) also having a plurality of side walls (20) connected to the perimeter (17) of the floor (10) and extending around some or all of the perimeter (17) and adapted to cover respective sides of an electronic device (30) in the tray, the floor (10) including at least one recess (40), the one or more recesses (40) connecting with at least two spaced apart slots (42) extending through the floor (10);
a flexible elastic band (50) extending over at least part of the outer surface (11) of the floor (10) and between the slots (42) for resiliently receiving items to be stored between the band (50) and the outer surface (11) of the floor, the band having at least two opposite flaps (51), each flap (51) extending through at least one of the slots (42) and into a recess (40), each flap (51) being secured within a recess (40); and
a cover plate (55) fixed within the tray (5), the cover plate (55) being sized and positioned to cover the flaps (51) and at least part of the inner surface (11) of the floor, the cover plate (55) also being positioned for contacting the rear surface (31) of the electronic device (30);
wherein the elastic band (50) is adapted to lie flat against the outer surface (11) of the floor; and
wherein the case (1) has a holding state wherein the elastic band (50) is stretched away from the outer surface (11) of the floor (10) to accommodate one or more items against the outer surface (11), and wherein the elastic band (50) exerts pressure on the items in the direction of the outer surface (11) of the floor to hold the items against the outer surface (11).

3. The case (1) for an electronic device (30) with added storage feature of claim 2, wherein the electronic device (30) is a cellular telephone comprising a touch screen.

4. The case (1) for an electronic device (30) with added storage feature of claim 2, wherein the electronic device (30) is selected from the group consisting of a computer and an electronic reading device, the electronic device (30) having a first dimension which is at least five inches and a second dimension which is at least seven inches.

5. The case (1) for an electronic device (30) with added storage feature of claim 2, wherein the case (1) has a thickness of no more than fifteen millimeters, inclusive of the elastic band (50), when flat against the outer surface (11).

6. The case (1) for an electronic device (30) with added storage feature of claim 2, wherein the elastic band (50) comprises nylon elastic.

7. The case (1) for an electronic device (30) with added storage feature of claim 2, wherein the band (50) and the outer surface (11) of the floor (10) collectively form an expandible space for resiliently receiving items to be stored, and wherein said space is open at two opposite ends.

8. The case (1) for an electronic device (30) with added storage feature of claim 2, further comprising two elastic bands (50) extending over at least part of the outer surface (11) of the floor (10) and between at least two slots (42), each elastic band (50) being for resiliently receiving items to be stored, each elastic band (50) comprising at least two opposite flaps (51), each flap (51) extending through a slot (42) and being secured within a recess (40).

9. The case (1) for an electronic device (30) with added storage feature of claim 2, wherein a recess (40) comprises a portion of the inner surface (12) which is sunken below the level of other portions of the inner surface (12).

10. The case (1) for an electronic device (30) with added storage feature of claim 2, wherein the case comprises a plurality of recesses (40), at least two of the recesses (40) being defined by at least one rib (15) on the inner surface (12) of the floor (10) and also by a portion of the side walls (20).

11. The case (1) for an electronic device (30) with added storage feature of claim 2, wherein the floor (10) comprises at least six recesses (40), the recesses (40) being defined including by a plurality of ribs (15) on the inner surface (12) of the floor (10).

12. The case (1) for an electronic device (30) with added storage feature of claim 2, wherein the floor (10) comprises at least one opening (16) there through, and wherein the cover plate (55) comprises are least one plate opening (56) which is aligned with the opening (16) of the floor (10).

13. The case (1) for an electronic device (30) with added storage feature of claim 2, wherein the side walls (20) comprise at least one opening (22) there through.

14. The case (1) for an electronic device (31) with added storage feature of claim 2, wherein the flaps (51) of the elastic band (50) are each fixed in a recess (40) using adhesive.

15. The case (1) for an electronic device (30) with added storage feature of claim 2, wherein the tray (5) and the cover plate (55) both comprise rigid plastic.

16. The case for an electronic device with added storage feature of claim 2, wherein two slots (42) of equal size are parallel to each other and are positioned adjacent to two different side walls (20) at opposite sides of the floor (10); and
wherein the two different side walls are also parallel to each other and are provided on opposite perimeters (17) of the floor (10) of the tray (5).

17. The case (1) for an electronic device (30) with added storage feature of claim 2, wherein two slots (42) are parallel and are at least five inches apart, and wherein the portion of an elastic band (50) which is stretched between the two slots (42) is at least three inches wide at its narrowest point.
